(19) United States
(12) Patent Application Publication
(10) Pub. No.: US 2023/0173788 A1
(43) Pub. Date: Jun. 8, 2023

(54) MICROMECHANICAL FUNCTIONAL ASSEMBLY WITH A TRIBOLOGICAL COATING

(71) Applicant: The Swatch Group Research and Development Ltd, Marin (CH)

(72) Inventors: Cédric FAURE, Cortaillod (CH); Christian MANASTERSKI, Rochefort (CH)

(73) Assignee: The Swatch Group Research and Development Ltd, Marin (CH)

(21) Appl. No.: 17/815,626

(22) Filed: Jul. 28, 2022

(30) Foreign Application Priority Data
Dec. 6, 2021 (EP) 21212556.1

(51) Int. Cl. B32B 9/00; B82Y 30/00; C09D 1/00

(52) U.S. Cl. CPC B32B 9/007; B82Y 30/00; C09D 1/00

(57) ABSTRACT

A micromechanical functional assembly including at least one first part with a first functional surface intended to enter into frictional contact with a second functional surface, the second functional surface belonging either to the first part or to at least one second part constituting with the first part the functional assembly, wherein the functional assembly includes the first functional surface and the second functional surface are formed by a first layer including ultrananocrystalline, nanocrystalline or microcrystalline diamond, the first layer being topped by a second layer including S and F atoms. It also relates to the method for functionalising diamond.

### TECHNICAL FIELD OF THE INVENTION

The present invention relates to a micromechanical functional assembly comprising at least one part provided with surfaces subjected to frictional contact requiring a tribological coating. The micromechanical functional assembly relates more specifically to a pair of micromechanical horological parts, cooperating mechanically with one another such as an escapement wheel and pallets of an anchor.

### TECHNOLOGICAL BACKGROUND

When technologies were first developed for making diamonds by chemical vapour deposition (CVD diamond) there were high hopes for tribology, due to the intrinsic hardness of diamond. Unfortunately, dry friction between two diamond surface is not tribologically viable as it leads to adhesion between the contacting horological parts. This is due to the formation of bonds between the carbon atoms (C-C) of the two partner materials of the Diamond vs Diamond pair. To minimise this adhesive effect, the Diamond vs Diamond material pair has to be in the presence of an environment with a relative humidity (%RH) at least equal to 50%. This threshold value of 50%RH makes it possible to supply micro-droplets of water (H₂O) in the contact surface. This reduces the tangential displacement force F_{T} of one surface relative to another. These micro-droplets therefore act as local lubricants favouring the relative movement of the contacting horological parts. Below this threshold value, the phenomenon of adhesion is exacerbated, with contact instabilities occurring in short loads times.

Thus, in the contact conditions of movement (low normal force and high tangential force), the global coefficient of friction, CoF, of the Diamond vs Diamond pair can be lower than 0.2 as illustrated in FIG. 1. Unfortunately, these environmental conditions do not guarantee the tribological stability of the material pair beyond 5 minutes of testing. Indeed, the frictional instabilities appear from 3.5 minutes of testing.

The challenge therefore relates to using this Diamond/Diamond pair in a micromechanical functional assembly while guaranteeing stable tribological behaviour without lubricant over a longer period of time.

### SUMMARY OF THE INVENTION

The subject-matter of the invention is to overcome the aforementioned disadvantages by modifying the tribological properties of the diamond layer. Indeed, as explained above, the hydrogen, oxygen or humidity atmospheres are difficult to maintain with long-term use. The subject-matter of the invention is to replace the atomic OH or H passivation bond caused by the aforementioned environments with other molecules. These extreme surface modifications for changing the tribological properties are achieved, according to the invention, by functionalising the diamond layer. More specifically, according to the invention, the layer of diamond is functionalised with a sulphur and fluorine compound.

Thus, the present invention relates to a micromechanical functional assembly comprising at least one first part with a first functional surface intended to come into frictional contact with a second functional surface, said second functional surface belonging either to said first part or to at least one second part constituting with said first part said functional assembly, said functional assembly being characterised in that the first functional surface and the second functional surface are formed by a first layer comprising ultrananocrystalline, nanocrystalline or microcrystalline diamond, said first layer being topped by a second layer including S and F atoms. It will be understood that the first layer can be made from the same material as the substrate constituting the first and second parts or different from the substrate.

An improvement in the tribological behaviour of these functional surfaces has been observed in tests. This improvement could be attributed to S which prevents the formation of (C-C) bonds when the relative humidity is no longer sufficient to perform this role. Thus, it is possible to provide functioning of a mobile horological system, such as a Swiss anchor escapement without lubrication of the pallet/escapement wheel contact, with performances that are at least equivalent to those of standard references.

This improvement in the tribological behaviour is observed more particularly when the two functional surfaces in contact are coated with a tribological layer of the same composition.

The present invention also relates to a method for functionalising diamond by reactive ion etching. Reactive ion etching is generally used for deep etching on silicon. It has been found by inventors that by using very low power reactive ion etching equipment, typically between 30 and 70 W, it is possible to synthesise this S and F compound on a part, such as a horology part which has small dimensions.

### BRIEF DESCRIPTION OF THE FIGURES

The aims, advantages and features will become apparent from the following figures:

FIG. 1 shows the curve of the global coefficient of friction (CoF_{(global)}) as a function of time, of the non-lubricated microcrystalline diamond/microcrystalline diamond pair according to the prior art, for a relative humidity of 30%;

FIG. 2 shows schematically in cross-section a portion of two parts of the functional assembly according to the invention;

FIG. 3 is a partial representation of a functional assembly comprising two parts, namely an escapement wheel and an anchor pallet with contact surfaces functionalised according to the invention;

FIG. 4 shows an electron microscopy image of the morphology of the second layer of S and F, with a rod structure;

FIGS. 5a and 5b show respectively the tribological results for a distance of 25 m, for a functional assembly comprising two parts; in FIG. 5a, for comparison not covered by the invention, one part is coated on its functional surface with microcrystalline diamond MCD and the other part with SF6 functionalised microcrystalline diamond; in FIG. 5b, according to the invention, the two parts are coated on their functional surface with SF6-functionalised microcrystalline diamond;

FIG. 6 shows the tribological results for the pair of FIG. 5b over a longer distance of 2500 m;

FIGS. 7a and 7b show respectively the amplitude of the balance wheel for a reference escapement wheel/anchor pair and an escapement wheel/anchor pair according to the invention with a layer of SF6 functionalised microcrystalline diamond;

FIG. 8 is a schematic view of the equipment used for the functionalisation of diamond.

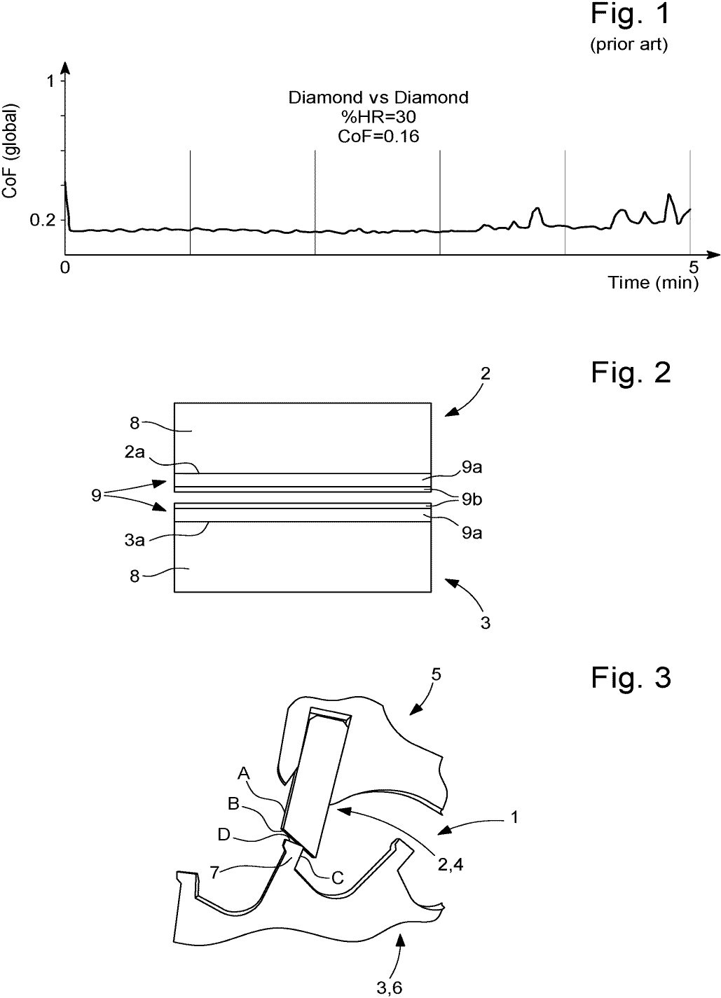

### DETAILED DESCRIPTION OF THE INVENTION

The present invention relates to a functional assembly comprising at least one part subjected to friction on its surface or surfaces referred to as functional or contact surfaces. The functional assembly according to the invention can include a single part with two functional surfaces intended to be in frictional contact. For example, in the field of horology, this may consist of a barrel spring formed by a blade with one face of the spring intended to be in contact with another face of the spring. Alternatively, the functional assembly can include at least two parts with each part respectively including a functional surface intended to be subjected to friction with a functional surface of another part. For example, in the field of horology, the functional assembly 1 can include a first part 2 which is a pallet 4 of an anchor 5 and a second part 3 which is an escapement wheel 6 as shown in FIG. 3. More precisely, the pallet 4 has a resting plane A and an impulse plane B which cooperate with the resting plane C and impulse plane D of the tooth 7 of the escapement wheel 6. These planes A, B, C, D are highly stressed functional surfaces and subject to high levels of friction and/or contact which may require a tribological layer according to the invention to reduce the friction. In another horological application, the first part can be a shaft of a mobile and the second part a bearing. According to another application in this field, the first and second parts can be gearwheel teeth.

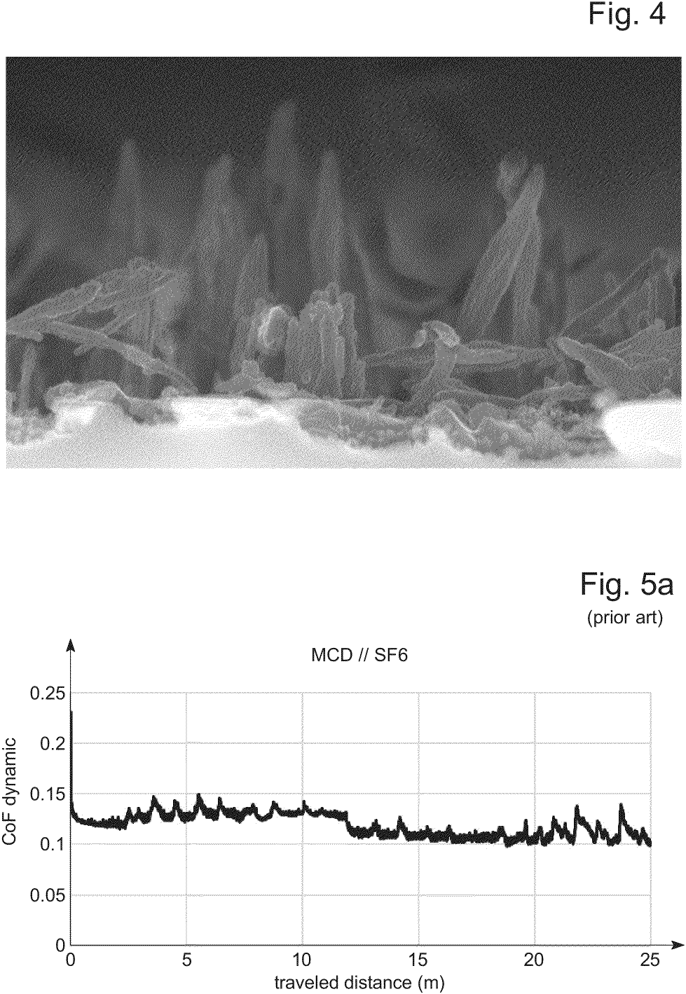

As depicted in FIG. 2, the functional assembly 1 includes the first part 2 and the second part 3 formed by a substrate 8 with at least the tribological layer 9 on their functional surface 2a,3a. This layer 9 is formed by a first layer of diamond 9a which can be UNCD (Ultrananocrystalline Diamond), NCD (Nanocrystalline Diamond) or MCD (Microcrystalline Diamond). According to the invention, this first layer 9a is functionalised with a sulphur compound, and more specifically S and F, which forms a second layer 9b on the first layer 9a. Advantageously, the first layer 9a is functionalised with SF6. Other gases such as SF2 and SF4 are possible, although they are more dangerous and of more limited use. Generally, the S and F functionalised on the surface of the layer of diamond are in the form of rods as shown in FIG. 4. The second layer of S and F generally has a non-constant thickness and is of nanometric dimensions typically with an average thickness of between 2 and 50 nm, more specifically between 5 and 10 nm. Suitable techniques for visualising and chemically analysing the second S and F layer are for example X-Ray photoelectron spectrometry: XPS) or Time that the layer is extremely thin, it may be difficult to identify the compound present precisely. Reference is therefore made to a layer comprising S and F.

According to the invention, the surfaces intended to be brought into contact are each covered with the layer of S- and F-functionalised diamond. The layer 9 including the first layer of diamond 9a and the second layer 9b of S and F has an average thickness of between 800 nm and 1200 nm, preferably between 900 and 1200 nm, this being MCD, NCD or even UNCD diamond.

For example, the substrates can be selected from a group of materials including ceramics, silicon, oxidised silicon, nitrided silicon, carburised silicon and steels. It is also possible that the substrate and the diamond layer form a single solid material. According to a preferred embodiment, the substrate is silicon with a layer of microcrystalline diamond functionalised with S and F.

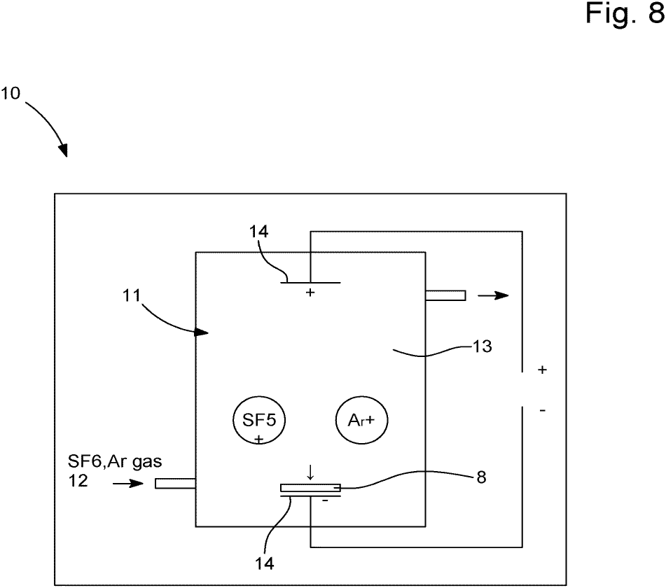

The method of functionalising the diamond layer is as follows. In advance, the diamond layer is deposited by chemical vapour deposition (CVD) or by the hot filament technique if the substrate is not solid diamond. Then, the sulphur and fluorine are deposited in the form of a second ultra-fine layer on the diamond layer by a very low power reactive ion etching method (RIE) in order to achieve deposition rather than etching. The equipment 10 for functionalising the diamond with the plasma reactor 11 is outlined in FIG. 8. This may be of the “capacitive coupling” type for example.

The parameters of the method are as follows:
reactive gas (12) comprising S and F such as SF6, SF4 or SF2, with a flow rate of between 3 and 20 sccm (Standard Cubic Centimetre per Minute), or cm³.min⁻¹, preferably between 5 and 10 sccm,
radiofrequency (RF) power between 30 and 70 W, preferably between 40 and 60 W,
pressure in the reactor between 30 and 150 µbar, preferably between 80 and 120 µbar,
reaction time between 20 and 120 minutes, preferably between 30 and 70 minutes.

The second functionalised layer obtained in this way has a very low thickness, in the order of several nanometres, even with a reaction time of in the order of one hour.

Tests were carried out to evaluate the tribological behaviour of a functional assembly according to the invention.

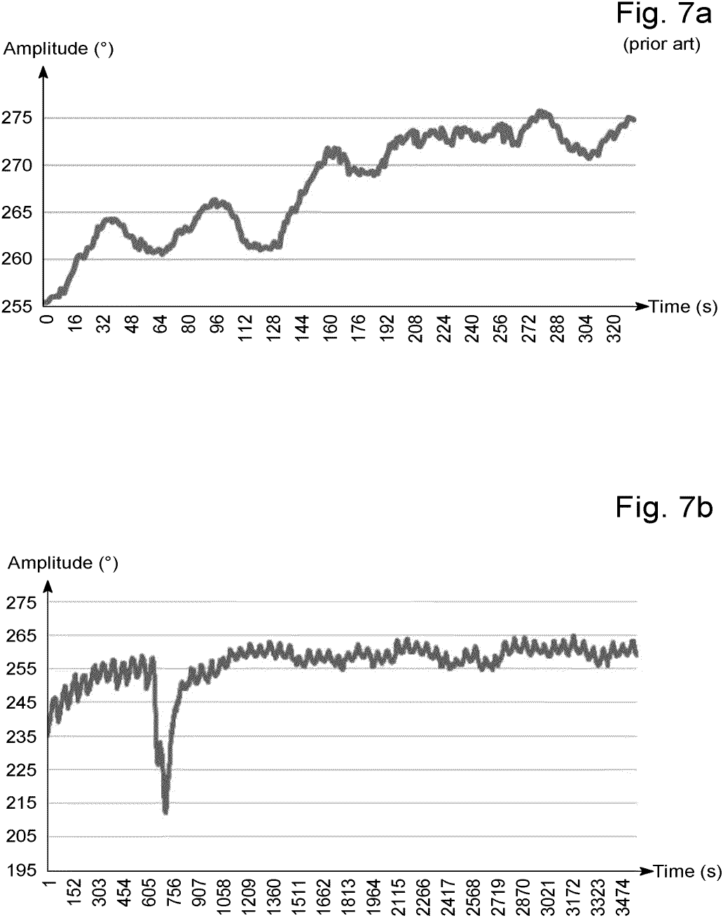

Escapement wheels made of Si as well as pallet lifts made of Si were coated with microcrystalline diamond functionalised with S and F and more specifically SF6. The tests were therefore carried out with a functionalised diamond/functionalised diamond pair and compared with a standard anchor with a lubricated steel on ruby contact. FEMTO-torque tests were carried out to measure the performance of a Swiss anchor escapement mounted on a work plate. The torque applied was 16 µN.m. The measurement of the amplitude of the balance wheel (with 3 arms) is shown in FIGS. 7a and 7b respectively for the standard anchor and the anchor treated according to the invention. For the standard anchor, the average amplitude is 274° for one hour of testing. For the anchor treated according to the invention, the average amplitude is 256° for one hour of testing, or 18° below that of the standard anchor. Apart from the temporary failure at 700 s, it can be seen that the regularity of the amplitude is very good, better than for the standard reference version.

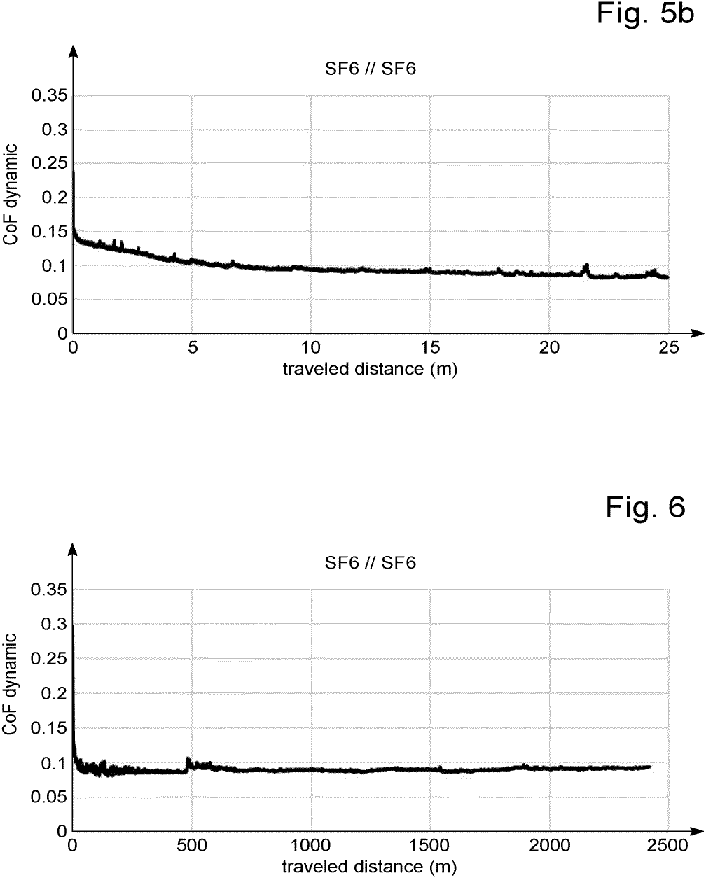

In parallel, tribological tests were also carried out with a ball/plane tribometer with a ball of 2 mm diameter for a distance of 25 metres and 2500 metres. The 25 metre tests were performed with a ball/plane pair each having an Si substrate with a layer of SF6 (SF6//SF6) functionalised diamond and with a comparative ball/plane pair where the ball is an Si substrate coated with microcrystalline diamond without functionalisation and where the plane is an Si substrate coated with microcrystalline diamond functionalised according to the invention (MCD//SF6). The purpose of these tests is to highlight the advantage of functionalising the two contact surfaces. The tests were carried out with a normal force of 10 mN, a sliding speed of 10 mm/s and an amplitude of 4 mm. The dynamic friction coefficient as a function of distance is shown in FIGS. 5a and 5b respectively for the comparative pair and the pair according to the invention. It can be seen that the average coefficient of friction for the comparative pair is greater than 0.1. It is not very stable with numerous peaks. On the other hand, for the pair according to the invention, the average coefficient of friction is less than 0.1 and stable. A longer test over a distance of 2500 metres was carried out on this same pair of according to the invention. The result is shown in FIG. 6. The average coefficient of friction is low and identical to that of the sort 25 metre test. After a short running-in period, the coefficient of friction is stable over the whole test period.

Thus, the FEMTO-torque tests and the tribological tests confirm the very good behaviour in use of the functionalised diamond on functionalised diamond pair.

### KEY

(1) Functional assembly
(2) First part
   a) First contact surface, also referred to as a functional surface
(3) Second part
   a) Second contact surface, also referred to as a functional surface
(4) Pallet
   A. Resting plane
   B. Impulse plane
(5) Anchor
(6) Escapement wheel
(7) Tooth
   C. Resting plane
   D. Impulse plane
(8) Substrate
(9) Tribological layer
   a) First layer comprising diamond
   b) Second layer comprising S and F
(10) Equipment for functionalisation
(11) Reactor
12) Gas
(13) Plasma
(14) Electrodes

1. A micromechanical functional assembly comprising at least one first part formed by a first substrate topped by a first functional surface intended to enter into frictional contact with a second functional surface, said second functional surface belonging either to said first part or to at least one second part formed by a second substrate topped by said second functional surface, the second part constituting with said first part said functional assembly, wherein said functional assembly comprises the first functional surface and the second functional surface are formed by a first layer which is either integral with the first substrate and the second substrate or distinct from the first substrate and the second substrate, the first layer comprising ultrananocrystalline, nanocrystalline or microcrystalline diamond and being topped by a second layer including S and F atoms and wherein the second layer has an average thickness of between 2 and 50 nm.

2. The functional assembly according to claim 1, wherein the second layer includes SF6.

3. The functional assembly according to claim 1, wherein the second layer is formed of rods.

4. The functional assembly according to claim 1, wherein the first part is a pallet and wherein the second part is an escapement wheel.

5. The functional assembly according to claim 1, wherein the first part is a shaft of a mobile and wherein the second part is a bearing.

6. The functional assembly according to claim 1, wherein the first part and the second part are gearwheel teeth.

7. The functional assembly according to claim 1, wherein said second functional surface belongs to said first part and wherein the first part is a barrel spring formed by a blade and wherein a front face of said blade forms said first functional surface and wherein the rear face of said blade forms said second functional surface.

8. The functional assembly according to claim 1, wherein the first substrate and the second substrate are selected from ceramics, silicon, oxidised silicon, nitrided silicon, carburised silicon and steels, when said first layer is distinct from the first substrate and the second substrate.

9. Method A method for functionalising ultrananocrystalline, nanocrystalline or microcrystalline diamond, comprising the following steps:
a) providing at least one first substrate coated with a first layer of said ultrananocrystalline, nanocrystalline or microcrystalline diamond or providing at least one first substrate made of ultrananocrystalline, nanocrystalline or microcrystalline diamond,
b) functionalising said first substrate of step a) in reactive ion etching equipment provided with a reactor and electrodes, the functionalisation being performed at a radiofrequency power of between 40 and 60 W, with as reactive gas a compound comprising S and F, the voltage between the electrodes being between 130 and 170 V.

10. The method according to claim 9, wherein the compound is SF6.

11. The method according to claim 9, that wherein the pressure in the reactor is between 30 and 150 µbar.

12. Method The method according to claim 9, wherein the flow rate of the reactant gas in the reactor is between 3 and 20 sccm.

13. The method according to claim 9, wherein the functionalising time of the first substrate in the reactor is between 20 and 120 minutes.

14. The method according to claim 9, wherein the equipment is provided with a capacitive plasma coupling.
